(19) United States
(12) Patent Application Publication
(10) Pub. No.: US 2024/0020929 A1
(43) Pub. Date: Jan. 18, 2024

(54) SYSTEM AND METHOD FOR PRESENTING CONSTRUCTION INFORMATION

(71) Applicant: TYRRELLS ADMINISTRATION PTY LTD, Erina (AU)

(72) Inventors: Jeremy TYRRELL, Erina (AU); Andrew JOHNSON, Erina (AU)

(21) Appl. No.: 18/246,807

(22) PCT Filed: Oct. 14, 2021
(86) PCT No.: PCT/AU2021/051202

§ 371 Date: Mar. 27, 2023

(30) Foreign Application Priority Data
Oct. 16, 2020 (AU) 2020903771

(51) Int. Cl. G06T 19/00; G06V 10/75; G06V 10/764; G06V 10/82; G06Q 50/08

(52) U.S. Cl. CPC G06T 19/006; G06V 10/751; G06V 10/764; G06V 10/82; G06Q 50/08

(57) ABSTRACT

A method of presenting construction-related information to a user is provided. The method comprises, at a computing device, receiving a user selection for a construction region, and retrieving image data for one or more construction components that form part of the selected construction region. The method further comprises retrieving construction information defining a construction requirement associated with one or more of the construction components, and rendering a first enhanced construction image that combines the retrieved image data for the construction components with a schematic representation of the construction information. The method may comprise receiving sensor data indicative of a location of the computing device, ascertaining a current location or geographical area of the computing device based on the received sensor data, and retrieving geospatial information associated with both the current location or geographical area and one or more of the construction components.

### TECHNICAL FIELD

The present disclosure relates, generally, to architecture, design and construction software tools, and, more particularly, to a system for, and a method of, presenting construction information to a user.

### BACKGROUND

There are a great number of standards, rules, and best practices to which a person responsible for a building project should adhere for building work such as a house, dwelling, cabana, pool, apartment block, or other building.

Traditionally, construction rules and acceptable practice, including building, concrete, materials, electrical, built areas, and the like, have been made available in printed form. The rules and acceptable practice are printed in bound and/or electronic versions, and often extend to hundreds or thousands of pages. These publications are filled with text, and while they necessarily prescribe certain thresholds, setbacks and other details, those thousands of details themselves present a problem; finding the detail relevant to any one task at hand becomes difficult and unwieldy.

Even when the books are provided as electronic files, so that they can be accessed on a person's mobile device or desktop or laptop, the information is set out in an ungainly fashion; details relevant to a task are difficult to find. First, the right rule or standard must be identified, and then, the right page and diagram must be identified. During the construction of an element, in the field, this arrangement of information is cumbersome.

Ultimately, a tradesperson, designer or engineer is likely to give up, and becomes reliant on memory for compliance with standards or rules, and memory is inaccurate.

Similarly, an assessment and comparison with workplace arrangement standards, rules or acceptable practice should be made when a person moves into an arrangement wherein they perform their daily workplace tasks from home, rather than an office environment. Workplace assessment provides a review of workplace ergonomic requirements.

As portable electronic devices become more compact, it has become challenging to design user interfaces that allow users to interact with applications easily. This challenge is particularly significant for portable devices with smaller screens and/or limited input devices. In addition, data visualization applications need to provide user-friendly ways to explore data in order to enable a user to extract meaning from a particular data set. Some application designers have resorted to using complex menu systems to enable a user to perform desired functions. These conventional user interfaces often result in complicated key sequences and/or menu hierarchies that must be memorized by the user and/or that are otherwise cumbersome and/or not intuitive to use.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each claim of this application.

### SUMMARY

Embodiments of the methods and systems described herein provide visual representations of construction and standards information with the aim to facilitate access to and interpretation of construction standards, rules, guidelines, and/or best practices. In some embodiments, the methods and standards facilitate compliance with construction and/or workplace arrangement standards.

Embodiments of the systems and methods provide a simpler and clearer way of accessing and interpreting data relating to building, construction and workplace arrangement standards when compared to, for example, having to laboriously leaf through hundreds or thousands of pages of written text, without much assistance from pictures or graphical representations that aid in interpreting standards.

Embodiments of the methods, devices, and graphical user interfaces (GUIs) described herein make viewing, understanding and manipulation of data sets and data visualizations more efficient and intuitive for a user. A number of different intuitive user interfaces for data visualizations are described below. For example, applying a filter to, selecting or enhancing a data set can be accomplished by a simple touch input on a given portion of a displayed data visualization rather than via a nested menu system.

In one aspect there is provided a method of presenting construction-related information to a user, the method comprising: at a computing device: receiving a user selection for a construction region; retrieving image data for one or more construction components that form part of the selected construction region; retrieving construction information defining a construction requirement associated with one or more of the construction components; rendering a first enhanced construction image that combines the retrieved image data for the construction components with a schematic representation of the construction information.

As used herein, “construction region” refers to a region or area where construction occurs, for example the building site where a domestic residence is being constructed. The construction region may include one or more buildings or built structures; for the example of a domestic residence building region, the region may also include outbuildings such as a shed.

As used herein, “construction components” refers to components or sections of a construction, such as a part of a building, for example a staircase, a roof, fencing, etc.

The schematic representation of the construction information may comprise at least one of: an image, a visual mark, a dimension indicator, and a colour indicator.

The method may further comprise: receiving sensor data indicative of a location of the computing device; ascertaining a current location or geographical area of the computing device based on the received sensor data; retrieving geospatial information associated with both the current location or geographical area and one or more of the construction components; and rendering a second enhanced construction image that includes additional content incorporating the retrieved geospatial information. The additional content may be in the form of a schematic representation.

The method may further comprise detecting a change in location of the computing device from the current location to a new location associated with new geospatial information, wherein detecting the change in location comprises ascertaining a change from the geospatial information to the new geospatial information.

The method may further comprise selecting the new location for a new enhanced construction image and displaying, as part of the new enhanced construction image, the new geospatial information. The new geospatial information may be displayed in the form of a schematic representation.

In another aspect there is provided a method of presenting a visual representation of construction information to a user, the method comprising: at a computing device with a display screen: displaying a construction image on the display screen, wherein the construction image displays:
a visual representation of a building element having a plurality of element zones on the building element, each element zone associated with a feature of the building element;
detecting a first user input that corresponds to a first location on the display of the construction image;
determining whether the first location is in an element zone, and based on the determination causing a transition on the display from the construction image to a zoomed in portion of the construction image, the zoomed in portion associated with the element zone; and displaying a visual representation of construction information associated with the user-selected feature of the building element.

In another aspect there is provided a method of presenting construction-related information to a user, the method comprising: at a computing device: receiving a user selection for building type; retrieving image data for one or more building elements that form part of the selected building type; retrieving construction information associated with one or more of the building elements; rendering a first construction image that combines the retrieved image data for the building elements with a visual representation of the construction information.

The visual representation of the construction information may comprise at least one of: an image, a visual mark, a dimension indicator, and a colour indicator. The method may further comprise: receiving GPS sensor data indicative of a location of the computing device; ascertaining a current location or geographical area of the computing device based on the received sensor data; retrieving geospatial information associated with both the current location or geographical area and one or more of the building elements; rendering a second construction image that includes additional content incorporating the retrieved geospatial information, wherein the geospatial information comprises at least one of: wind loading, temperature ranges, rainfall ranges, and insect pests; wherein the additional content comprises construction requirements associated with the geospatial information.

In another aspect there is provided a method of presenting construction standards, the method including the steps of: representing one or more of a section, or exploded, or cutaway, view of a building on a display screen of a computer processing system; providing zoomable, clickable or otherwise selectable areas, on the display screen of the computer processing system, which represent relevant building elements; presenting, on the display screen of the computer processing system, in response to a user clicking or otherwise selecting the relevant areas on the screen, detailed information relating to construction standards for the relevant element or elements.

The detailed information presentation step may include presenting annotated images of the element.

In another aspect there is provided a system for facilitating compliance with building and/or workplace health standards, the system including: a computer processing system comprising: a user interface configured to: represent one or more of a section, or exploded, or cutaway, view of a building on a display screen as an image; and receive a user input indicative of a selected building element on the building representation; wherein the computer processing system is further configured to cause detailed information relating to construction standards of the relevant element or elements to be displayed on a screen of the computer processing system, in response to the received user input.

The computer processing system may further be configured to display the detailed construction standard information as a graphical representation comprising annotated images of the element.

The annotations on the image may include dimensions from one element to another element, in accordance with a relevant standard, wherein the dimensions are presented as a graphical representation superimposed on the image of the building.

In another aspect there is provided a computer-implemented method of visualising data, the method comprising: at a computing device with a display screen: accessing image data associated with a building having one or more building elements; retrieving construction information about the one or more building elements, the construction information including at least one of compliance information, construction standards information, and construction best practice information; rendering a pictorial representation of the construction information onto the image data to create a construction image comprising an image of a building element of the building and annotated construction information; and causing the display screen to display the construction image.

In another aspect there is provided a method of presenting information to a user, the method comprising:
accessing, by a computing device, image data representing a view of a building and construction information associated with the image view data, the construction information comprising at least one of compliance information, construction standards information, and construction best practice information;
generating, on a user interface shown on a display screen coupled to the computing device, representations of a construction region;
providing, on the user interface, an option to the user to make a display selection to view a building element in the construction region;
generating, on the user interface and in response to receiving the instruction from the user, a display of a transition that originally presents a first construction image and concludes the transition, via intermediate displays, by displaying a second construction image.

In another aspect there is provided a method of presenting construction-related information to a user, the method comprising: at a computing device: receiving a user selection for a construction region; retrieving image data for one or more construction components that form part of the selected construction region; retrieving construction information associated with one or more of the construction components; rendering a first construction image that combines the retrieved image data for the construction components with a visual representation of the construction information.

The visual representation of the construction information may comprise at least one of: an image, a visual mark, a dimension indicator, and a colour indicator.

The method may further comprise: receiving sensor data indicative of a location of the computing device; ascertaining a current location or geographical area of the computing device based on the received sensor data; retrieving geospatial information associated with both the current location or geographical area and one or more of the construction components; rendering a second construction image that includes additional content incorporating the retrieved geospatial information.

In another aspect there is provided a method of presenting a visual representation of construction information to a user, the method comprising: at a computing device with a display screen: displaying a construction image on the display screen, wherein the construction image displays: a visual representation of a construction component having construction elements, and element zones on the construction component associated with the construction elements; detecting a first user input that corresponds to a first location on the display of the construction image; determining whether the first location is in an element zone, and based on the determination causing an animated transition to display a construction view of a construction element associated with the element zone; and displaying a visual representation of construction information associated with the user-selected construction element.

In another aspect there is provided a computer-implemented method of visualising data, the method comprising: at a computing device with a display screen: accessing image data associated with a construction component having one or more construction elements; retrieving construction information about the one or more construction elements; rendering a pictorial representation of the construction information onto the image data to create a construction image; and causing the display screen to display the construction image.

In another aspect there is provided a method of presenting information to a user, the method comprising: accessing, by a computing device, image view data and construction information associated with the image view data; generating, on a user interface shown on a display screen coupled to the computing device, representations of a construction region; providing, on the user interface, an option to the user to make a display selection to view a construction component in the construction region; generating, on the user interface and in response to receiving the instruction from the user, a display of an animated transition that originally presents a first construction image and concludes the animated transition, via intermediate displays, by displaying a second construction image.

In another aspect there is provided a method of presenting information to a user, the method comprising: presenting, with an application on a computing device, a representation of a construction component on a display screen of the computing device; obtaining sensor data from a sensor associated with the computing device; determining, based on the sensor data, that the computing device is in a first geographical area having a first geospatial parameter; presenting a first construction image associated with the construction component in response to determining that the computing device is in the first geographical area; detecting a change in location of the computing device from the first geographical area to a second geographical area associated with a second geospatial parameter, wherein detecting the change in location comprises ascertaining a change from the first geospatial parameter to the second geospatial parameter.

The method may further comprise selecting the second geographical area for a construction image and displaying, as part of the construction image, the second geospatial parameter.

In another aspect there is provided a computing device comprising a processor and a memory having instructions that when performed cause the electronic device to perform a method as described above.

### BRIEF DESCRIPTION OF DRAWINGS

Embodiments of the disclosure are now described by way of example with reference to the accompanying drawings in which:

FIG. 1 is a system diagram of an example embodiment of a computing system in which techniques outlined herein can be implemented.

FIG. 2 shows an example embodiment of a construction display showing a construction region.

FIG. 3 shows an example embodiment of an enhanced construction image of a construction component.

FIG. 4 shows an example embodiment of an enhanced construction image of a construction element.

FIGS. 5A-5D show an embodiment of collection of enhanced construction images for a stair construction component.

FIG. 6 shows an embodiment of an enhanced construction image for the stair construction component of FIGS. 5A-5D.

FIG. 7 shows an embodiment of a calculation tool.

FIGS. 8A-8E illustrate user navigation of a collection of enhanced construction images associated with a construction region.

FIG. 9A shows an embodiment of a first construction display that displays risk indicators.

FIG. 9B shows an embodiment of a second construction display that displays risk indicators.

FIG. 10 shows an embodiment of an enhanced construction image for workplace compliance.

FIG. 11 shows an embodiment of a method of presenting construction-related information to a user.

In the drawings, like reference numerals designate similar parts.

### DESCRIPTION

Example Hardware and Software Components

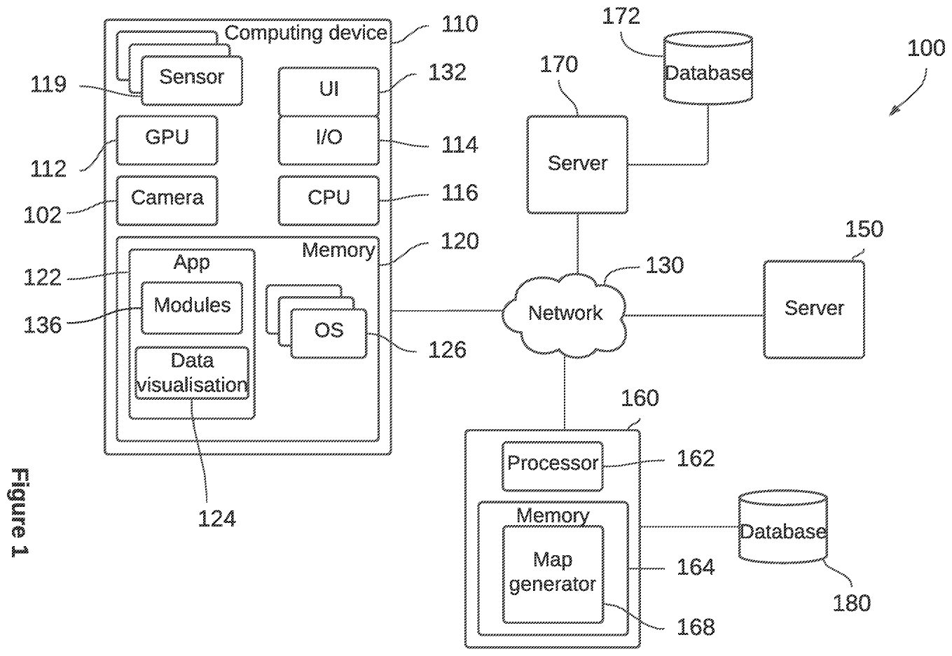

Referring to FIG. 1, an example system 100 in which the techniques outlined herein can be implemented includes a computing device 110, such as a portable device configured to execute a construction application 122. The computing device is in communication with one or more servers 150, 160, 170 via a communication network 130, such as the Internet, which interconnects the devices operating in the system 100.

Computing Device 110:

In an example implementation, the computing device 110 may be a portable multifunction device such as smart phone or a tablet computer, for example, and includes a memory 120, one or more processors (CPUs) 116, a graphics processing unit (GPU) 112, an I/O module 114, a user interface (UI) 132, an image sensor, e.g. in the form of a camera 102, and one or more sensors 119. The memory 120 can be a non-transitory memory and can include one or more suitable memory modules, such as random access memory (RAM), read-only memory (ROM), flash memory, other types of persistent memory, etc. The I/O module 114 may be a touch screen (sometimes called a touch-sensitive display and/or a touch-sensitive display system).

Touch Screen 114 & User Inputs:

In some implementations, the touch screen 114 displays one or more graphics within UI 132. In some implementations, a user is enabled to select one or more of the graphics by making a touch input on the graphics. In some instances, the touch input is a contact on the touch screen. In some instances, the touch input is a gesture that includes a contact and movement of the contact on the touch screen. In some instances, the gesture optionally includes one or more taps, one or more swipes (from left to right, right to left, upward and/or downward) and/or a rolling of a finger (from right to left, left to right, upward and/or downward) that has made contact with device 110. For example, a touch input may be made with one or more fingers or one or more styluses. In some implementations, selection of one or more graphics occurs when the user breaks contact with the one or more graphics displayed on the screen. In some circumstances, inadvertent contact with a graphic does not select the graphic. For example, a swipe gesture that sweeps over a visual mark optionally does not select the visual mark when the gesture corresponding to selection is a tap. In some implementations, the device 110 includes one or more physical buttons and/or other input/output devices, such as a microphone for verbal inputs.

In some embodiments the I/O module 114 includes a touch input sub-module and a graphics sub-module. In some implementations, the touch input sub-module detects touch inputs with a touch screen and other touch sensitive devices (e.g., a touchpad or physical click wheel). The touch input sub-module includes various software components for performing various operations related to detection of a touch input, such as determining if contact has occurred (e.g., detecting a finger-down event), determining if there is movement of the contact and tracking the movement across the touch-sensitive surface (e.g., detecting one or more finger-dragging events), and determining if the contact has ceased (e.g., detecting a finger-up event or a break in contact). The touch input sub-module receives contact data from the touch-sensitive surface (e.g., the touch screen). In some implementations, these operations are applied to single touch inputs (e.g., one finger contacts) or to multiple simultaneous touch inputs (e.g., multitouch/multiple finger contacts). In some implementations, the touch input sub-module detects contact on a touchpad.

In some implementations, the touch input sub-module detects a gesture input by a user. Different gestures on the touch-sensitive surface have different contact patterns. In some implementations, a gesture is detected by detecting a particular contact pattern. For example, detecting a finger tap gesture includes detecting a finger-down event followed by detecting a finger-up (lift off) event at the same position (or substantially the same position) as the finger-down event (e.g., at the position of a data mark). As another example, detecting a finger swipe gesture on the touch-sensitive surface includes detecting a finger-down event followed by detecting one or more finger-dragging events, and subsequently followed by detecting a finger-up (lift off) event.

The graphics sub-module includes various software components for rendering and displaying graphics on the touch screen or other display, including components for changing the visual impact (e.g., brightness, transparency, saturation, contrast or other visual property) of graphics that are displayed. As used herein, the term “graphics” includes any object that can be displayed to a user, including data visualizations, icons (such as user-interface objects including soft keys), text, digital images, animations, and the like. In some implementations, the graphics sub-module stores data representing graphics to be used. In some implementations, each graphic is assigned a corresponding code. The graphics sub-module receives (e.g., from applications) one or more codes specifying graphics to be displayed along with, if necessary, coordinate data and other graphic property data, and then generates screen image data to output to the display or touch screen.

In some embodiments the I/O module 114 may include a microphone or other type of sensor system such as a virtual reality or augmented reality user interface.

Other Computing Devices:

More generally, the techniques of this disclosure can be implemented in other types of devices, such as laptop or desktop computers, wearable devices, such as smart watches or smart glasses, etc. The device 110 need not be portable. In some implementations, the device 110 is a laptop computer, a desktop computer, a tablet computer, or an educational device that includes a screen 114, for example with a touch-sensitive surface. In some implementations, a user is enabled to select one or more of the graphics by making a touch input on a touch-sensitive surface of the screen 114 such that a corresponding cursor on the screen selects the one or more graphics. For example, when an input is detected on the touch-sensitive surface while the cursor is over a particular user interface element (e.g., a button, window, slider or other user interface element), the particular user interface element is adjusted in accordance with the detected input.

Touchscreens and Other Screens:

Although example embodiments described herein may utilise a touch screen, it should be understood that, in some implementations, the inputs (e.g., finger contacts) may be detected on a touch-sensitive surface on a device that is distinct from a display on the device. In addition, while the examples herein may be with reference to finger inputs (e.g., finger contacts, finger tap gestures, finger swipe gestures), it should be understood that, in some implementations, one or more of the finger inputs may be replaced with input from another input device (e.g., a mouse-based input or stylus input). For example, a swipe gesture is, optionally, replaced with a mouse click (e.g., instead of a contact) followed by movement of the cursor along the path of the swipe (e.g., instead of movement of the contact). As another example, a tap gesture is, optionally, replaced with a mouse click while the cursor is located over the location of the tap gesture (e.g., instead of detection of the contact followed by ceasing to detect the contact). Similarly, when multiple user inputs are simultaneously detected, it should be understood that multiple computer mice are, optionally, used simultaneously, or a mouse and finger contacts are, optionally, used simultaneously.

Memory 120:

The memory 120 stores various programs, modules, and data structures, or a subset thereof, such as operating system (OS) 126 that includes procedures for handling various basic system services and for performing hardware dependent tasks. OS) 126 can be any type of suitable mobile or general-purpose operating system. The OS 126 can include application programming interface (API) functions that allow applications (such as the construction application 122) to retrieve sensor readings. For example, a software application configured to execute on the computing device 110 can include instructions that invoke an OS 126 API for retrieving a current location and/or orientation of the computing device 110 at that instant. The memory 120 also stores the construction application 122, which is configured to generate interactive enhanced construction images. The construction application 122 can receive construction view data in a raster (e.g., bitmap) or non-raster (e.g., vector graphics) format from the server device 160. A data visualization module 124 implemented in the construction application 122 then renders a construction display based on the construction view data.

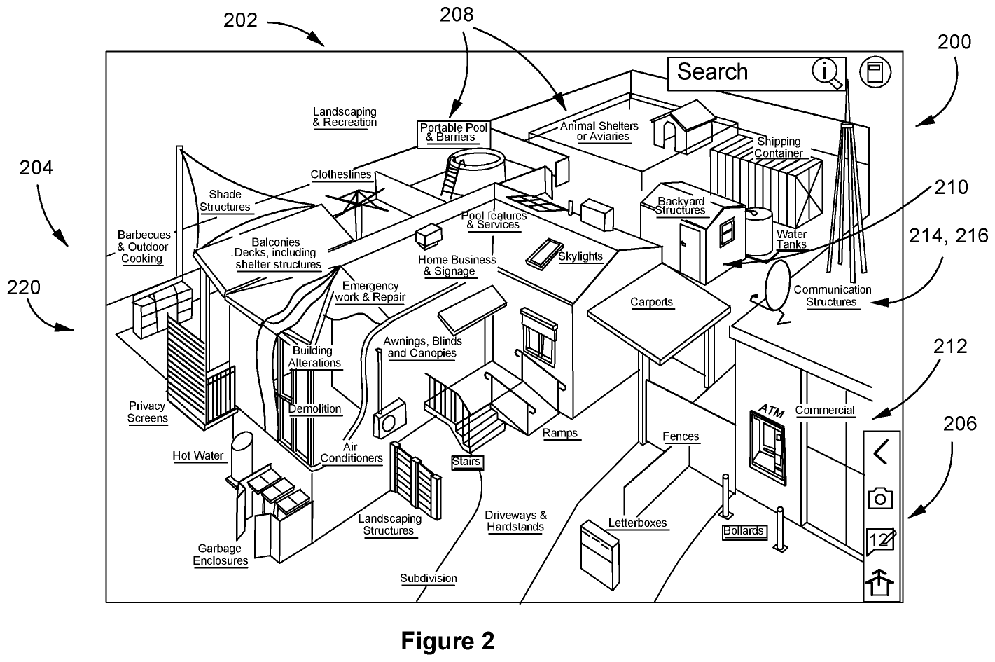

Referring to FIG. 2, a construction display 200 is displayed on the screen of a user device. The construction display 200 includes an enhanced construction image 202 (in this instance of a construction region 204), and a menu 206 for navigating the features of the construction application 122. The construction region 204 in this example is a domestic residence, so that the construction view 220 used for this enhanced construction image 202 is an image of a domestic residence and its associated construction components 208. The construction region 204 includes various construction components 208 such as portable pools and barriers, landscaping structures, carports, garbage enclosures, and backyard structures 210. Other types of construction regions may be, for example, a commercial building 212. The enhanced construction image 202 includes selectable zones 214, in this embodiment in the form of labels 216 for the various construction components 208.

The data visualization module 124 of the application 122 is used for displaying graphical views of data. The data visualization module 124 includes executable instructions for displaying and manipulating various graphical views of data. The data visualization module 124 provides a graphical user interface for constructing visual graphics based on one or more data sources (which may be stored on the computing device 110 and/or stored remotely).

Server 160:

Referring again to FIG. 1: in addition to the computing device 110, the system 100 includes a server device 160. In some embodiments, the server device 160 is configured to provide a construction display to the computing device 110. The server device 160 can be communicatively coupled to a database 180 that stores, in an example implementation, construction views for various construction types. For example, the construction views may correspond to residential or commercial building types, outdoor construction areas, particular construction components (such as stairs or fencing), etc.

In some implementations, the server device 160 includes one or more processors 162 and a memory 164. The memory 164 may be tangible, non-transitory memory and may include any types of suitable memory modules, including random access memory (RAM), read-only memory (ROM), flash memory, other types of persistent memory, etc. The memory 164 stores instructions executable on the processors 162 that make up an enhanced construction image generator 168, which can generate construction displays to be displayed by the construction application 122 for a construction region. The system 100 can include a data server 150 that provides construction data to the server device 160 for generating the construction display. The “construction data” may include data relating to standards, codes, guidelines, best practice, rules, etc. The memory 164 of the computing device 110, or the memory in another server, can store instructions that access and/or generate construction information (including e.g., standards information, rules, acceptable practice, and other construction-related information).

“Construction information” refers to information that defines one or more construction requirements such as construction standards, rules, codes, acceptable practice, best practice, etc. Construction requirements may be in the form of required dimensions, required materials, and/or required construction methods or techniques. In some embodiments the construction information may also include risk information indicating a risk level, risk type, risk consequences, etc. that describe the risk(s) associated with one or more construction elements.

The data visualization module 124 of the construction application 122 renders an enhanced construction image in which the construction information is overlayed or otherwise combined with construction views.

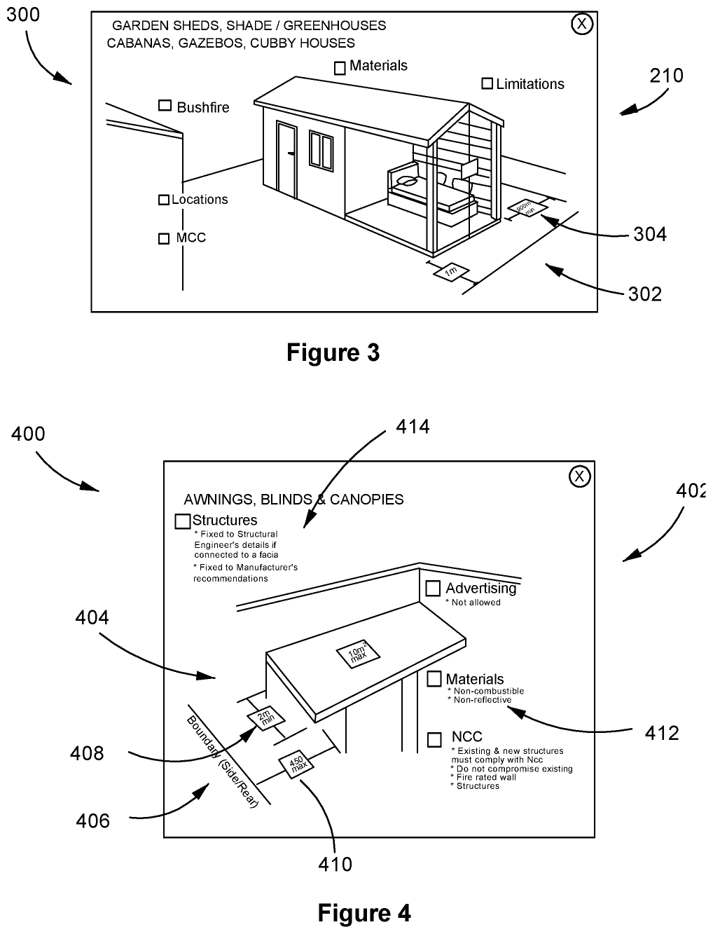

Referring to FIG. 3, an enhanced construction image 300 is shown for the backyard structure 210 construction component of the construction region 204 illustrated in FIG. 2. The enhanced construction image 300 includes a construction view 302 of a backyard structure (e.g. a garden shed, green house, cabana, gazebo or cubby house), together with construction information 304 associated with the construction component.

For simplicity, FIG. 1 illustrates the server device 160 as only one instance of a server. However, the server device 160 according to some implementations includes a group of one or more server devices, each equipped with one or more processors and capable of operating independently of the other server devices. Server devices operating in such a group can process requests from the computing device 110 individually (e.g., based on availability), in a distributed manner where one operation associated with processing a request is performed on one server device while another operation associated with processing the same request is performed on another server device, or according to any other suitable technique. For the purposes of this discussion, the term “server device” may refer to an individual server device or to a group of two or more server devices.

Each construction view may include a two-dimensional representation, a three-dimensional representation, or a combination of two-dimensional and three-dimensional representations. The representations may be images, photos, diagrams or the like, that describe a construction type (i.e., a house, a shed, etc). In some embodiments, each construction view may be from the perspective of a virtual camera having a particular view frustum. The view frustum may correspond to a camera location in three dimensions (e.g., the user's current location), a zoom level, and camera orientation parameters such as pitch, yaw, roll, etc., or camera azimuth, camera tilt, for example.

In some cases, the construction view data can be organized into layers, such as a construction region layer depicting a construction region (e.g., a residential property including a house and outdoor area), a construction component layer depicting construction components (e.g., backyard structures, fencing, windows, etc.), and a construction element layer depicting construction elements (e.g., awnings, gates, materials, etc.). Some embodiments also include a construction features layer depicting construction features that make up, form part of, or characterise construction elements.

As used herein, “construction elements” refers to elements, parts, or sub-components of a construction component.

Referring to FIG. 4 of the drawings, the enhanced construction image 400 provides information about an “awnings, blinds & canopies” construction element 402. The construction view 404 shows an image of an example awning, and the construction information 406 includes dimensions 408 e.g. construction standards-based dimensions such as a distance to a boundary 410. The enhanced construction image 400 includes information about construction features, including material information 412 and structure information 414.

The server device 160 can combine the construction view with the construction information in several ways. For example, the server device 160 may identify a portion of the construction view which represents a construction component or construction element and filter out or mask the part of the construction view around this portion. The server device 160 may then overlay the construction information on the construction component/element and/or on the filtered-out part of the construction view. This may require scaling the construction view or removing sections of the construction view so that the resulting enhanced construction image representation fits within the boundaries of the construction display.

In another implementation, the construction display may be composed on the computing device 110 rather than the server 160. For example, the enhanced construction image generator 168 on the server device 160 may transmit construction view data corresponding to the construction region and construction information corresponding to said construction region to the computing device 110. The computing device display 114 may then render the construction display based on the received construction view and construction data. In yet other embodiments, the construction display may be composed using some combination of the computing device 110 and the server device 160.

It is noted that although FIG. 1 illustrates the construction application 122 as a standalone application, the functionality of the construction application 122 can be provided in the form of an online service accessible via a web browser executing on the computing device 110, as a plug-in or extension for another software application executing on the computing device 110, etc. The construction application 122 generally can be provided in different versions for different respective operating systems.

Construction Information

Application 122 is configured to provide a visual representation, and in particular a superimposed schematic representation, of construction information with respect to a construction region and/or construction components. The method includes representing one or more of a section, or exploded, or cutaway, view of a building (such as a backyard structure 210) on a display 114 of a computing device 110; providing zoomable, clickable or otherwise selectable zones 214 (for example in the form of labels 216) on the display 114 of the computer computing device 110. The selectable areas 214 represent relevant construction components (and/or construction elements and/or construction features) of the construction region, presenting, on the display 114 of the computing device 110, in response to a user clicking or otherwise selecting the relevant areas on the screen, detailed construction information for the relevant construction component, element, and/or feature.

Construction information may include construction standards information, construction best practice information, geospatial information, and/or risk information. Construction standards information includes rules and regulations from construction codes and construction standards; this information may relate to mandatory construction requirements. Best practice information does not necessarily relate to rules or regulations from construction codes or construction standards; best practice information may include information relating to construction best practice that are not mandatory but optional. Geospatial information (as described elsewhere herein) relates to both mandatory standards-related requirements as well as best practice guidelines that are affected by the physical location of the construction. For example, in coastal areas steel thickness requirement may differ from inland steel thickness requirements.

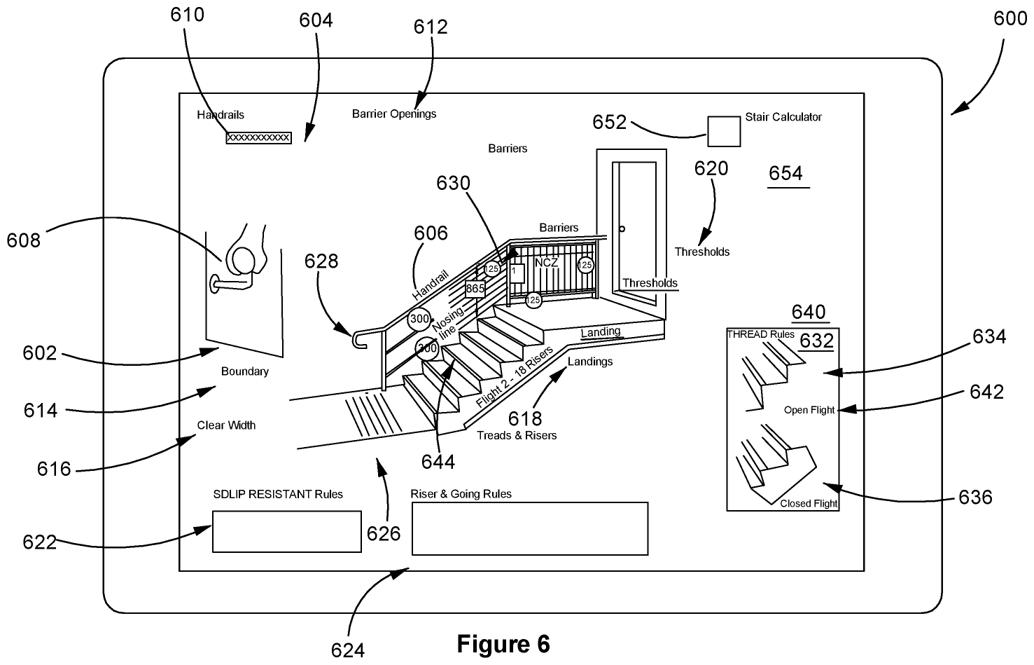

Risk is the possibility of danger, loss, injury or other adverse consequences. Risk information is provided to indicate the level of risk associated with construction information, for example associated with any one or more of the construction standards information, the construction best practice information, and the geospatial information. Risk information may be provided in the form of a risk indicator (for example an icon, a type of shading, a colour coding, animation, etc.) to indicate a level of risk. For example, information provided in red may indicate a high risk level for a requirement that is mandatory, and a non-compliance consequence may include death, major injury, and/or a high risk of damage. In this example, information provided in orange may indicate a moderate risk level for a requirement that is mandatory, and a non-compliance consequence may include minor or no injury risk and/or low risk of damage. Information provided in blue may indicate a low risk level for a best practice guideline only. Referring to FIG. 6, for example, the curvature degrees 628 may be schematically represented in orange to indicate a moderate risk, whereas the no climb zone 630 may be schematically represented in red to indicate a high risk. Similarly, the annotated requirements for the barrier openings 612 may include a high-risk (e.g. red-coloured) indicator relating to the 125 mm limitation for landing or nosing line separation from the bottom rail of the barrier, and may also include a medium-risk (e.g. orange-coloured) indicator relating to the 300 mm limitation for the openings of internal stairs.

In some embodiments, risk indicators may be associated with monetary cost, cosmetic/aesthetic effects, legal consequences, or other factors considered in decision-making for construction.

In some embodiments, the risk indicator is a two-dimensional indicator that incorporates both the severity of the potential consequences associated with the risk, and the likelihood of the event occurring that is associated with the risk factor. A schematic representation of the risk indicator (for example a colour coding, a symbol, animation, or other graphical representation) may be superimposed on the visual representation of the construction region, component or element to make it easier for the user to understand the risk implications of specific construction elements or components. For example, where high risk requirements are schematically represented with the use of colour, then an enhanced construction image with predominantly red annotations (for example), can be interpreted by a user, easily and at a glance, as a high risk or highly regulated construction element.

Geospatial Information

In some embodiments, the one or more sensors 119 (shown in FIG. 1) can include a global positioning system (GPS) module to detect the position of the computing device 110, a compass to determine the direction of the computing device 110, a gyroscope to determine the rotation and tilt, an accelerometer, etc.

In some embodiments, the server device 160 can communicate with one or several databases 172 (e.g., via a geospatial data server 170) that store geospatial information or information that can be linked to a geographic context, such as local weather patterns (e.g., relating to wind loading for the selected area, temperature ranges, rainfall ranges), location-specific standards, best practice guidelines, or construction-related information such as likely pests in a particular location.

In operation, the construction application 122 operating in the computing device 110 sends data to the server device 160. Thus, in one example, the server device 160 can receive a request for construction data for a geographic area including a geographic location, such as the current location of the user. In response, the server device 160 may retrieve geospatial information (such location-specific standards). The server device 160 may receive a user input selecting, for example, a construction region, or a construction type. In response, the server 160 retrieves an enhanced construction image. Accordingly, the server device 160 may combine the relevant construction view with the relevant construction information as well as the geospatial information to form an enhanced construction image, and provide a construction display with the enhanced construction image to the computing device 110.

Utility Modules

Construction application 122 may include one or more utility modules 136, for example a measurement module, an image processing module, a classification module, a certification module, a compliance module, etc. The utility modules 136 extend the functionality of construction application 122.

In some embodiments, a measurement module is used to implement a measurement step in which the computing device 110 provides on the display screen 114 one or more user input fields to receive measurement data of a construction component or a construction element and/or other data such as image data of the construction component or construction element from which measurement data can be calculated.

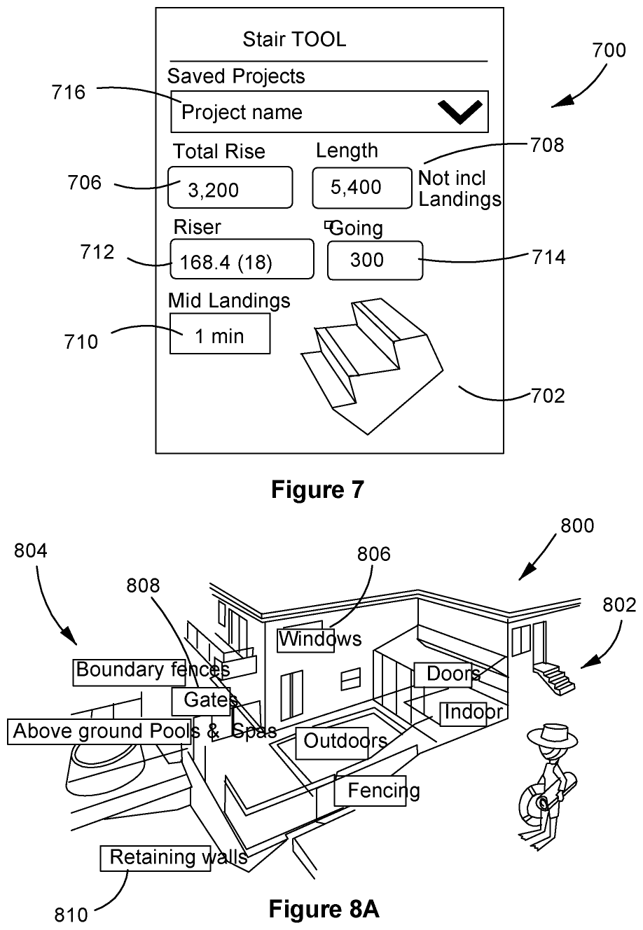

Some embodiments may include a calculation tool such as a stair tool 700 as shown in FIG. 7 and described elsewhere herein.

Some embodiments may include a distance measurement tool. The distance measurement tool may be configured to record measurements by utilising a measurement application, which measures angle of movement of a device, and the distance from the device. In some embodiments, the camera 102 may be configured to record measurements by a photogrammetry image processing application, or a laser or infra-red device, or any combination of these elements. In some embodiments, the camera 102 may be used to record building element and context point measurements by utilising a measurement application which uses photogrammetry or LIDAR or other means, to measure the distance of the building elements and contextual points from the device. In some embodiments, the application 122 may receive measurement information from a camera disposed on or connected to the computing device 110. In some embodiments, the application 122 may provide user input fields to receive any one of measurement data of a nearby building element, the context of the nearby building element, or other details of construction elements.

In some embodiments the computing device 110 is configured to facilitate the measurement and assessment of construction elements and the images include dimensions from one portion of an element to another portion of an element, in accordance with a relevant standard, rule, guideline, etc. Some embodiments include image processing to identify building or room elements so as to facilitate measurement of one feature to another with an inbuilt camera.

In one embodiment an image processing module is provided which includes a machine learning application. The machine learning application is configured to receive image information from the camera, and compare the image information from the camera with construction component and/or construction element information, for example from a standard construction element information database.

In some embodiments, the application 122 includes a classification module. The server device 160 may retrieve and provide to the classification module feature classifiers containing several characteristics used to identify pixels which represent construction features, construction elements or construction components. Based on the feature classifiers, the classification module may identify construction features and remove superfluous portions of an image (i.e., that do not relate to the identified construction features). Various classification systems such as support vector machines, neural networks, naive Bayes, random forests, etc. may be utilised. The filtering process that removes portions of the image may be performed using a spatial heuristic algorithm, using machine learning techniques to compare pixels in the panoramic view to sample pixels, or in any other suitable manner.

In some embodiments, the classification module passes the classification to a compliance module.

The compliance module compares aspects of the standard building element information (from database 180 via network 130) with the measurement information (determined, calculated, or input by a user) to assess whether the building element or its context is compliant with the relevant building codes or standards. In some embodiments, the compliance module utilises a lookup table either stored on board the memory 120 of the device 110 or in the online database 180 or in another processor accessible via the network 130.

In some embodiments, the application 122 provides a user interface that receives user inputs to a compliance checklist, and the finalised checklist can be saved, printed, or sent to a defined recipient for the purposes of building or construction compliance.

In some embodiments, application 122 includes an education module configured to provide educational features, track user navigation of educational features, and record user interaction with educational features provided via the construction display. In some embodiments the provision, tracking, and/or recording of educational features may relate to one or more of the following: a sharing option to share a screen with another user, time spent navigating through screens of annotated construction elements, the number of screens of annotated construction elements a user accesses and the time spent on each screen, the number of times that a user shares an annotated construction element screen (for example with a user of another instance of the application 122). In some embodiments, the education module may assign a weight to user actions, for example to the time spent on each screen, number of shares, number of screens over a selected time period, etc.

In some embodiments the education module may provide a discussion board and track user participation in a discussion board on a topic of relevance to annotated construction elements. In some embodiments the education module may provide a continuing professional development (CPD) report for use with a course of study or a certification.

Methods

Described below are various methods providing a visual presentation of annotated building elements, for example methods for presenting compliance information and/or facilitating compliance with one or more construction and/or other building codes and/or construction standards, various methods for providing an interactive graphical representation of a building or part, and which is configured to present code information marked up thereon so as to provide applied building code or construction standard information or assessment, and methods for facilitating assessment of workplace arrangements or compliance with construction codes.

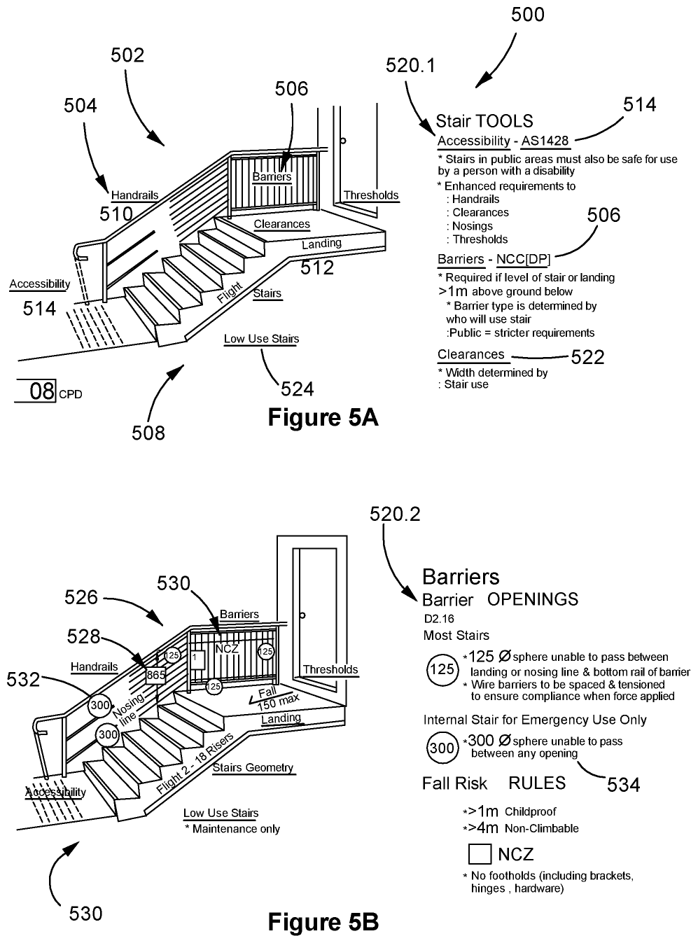

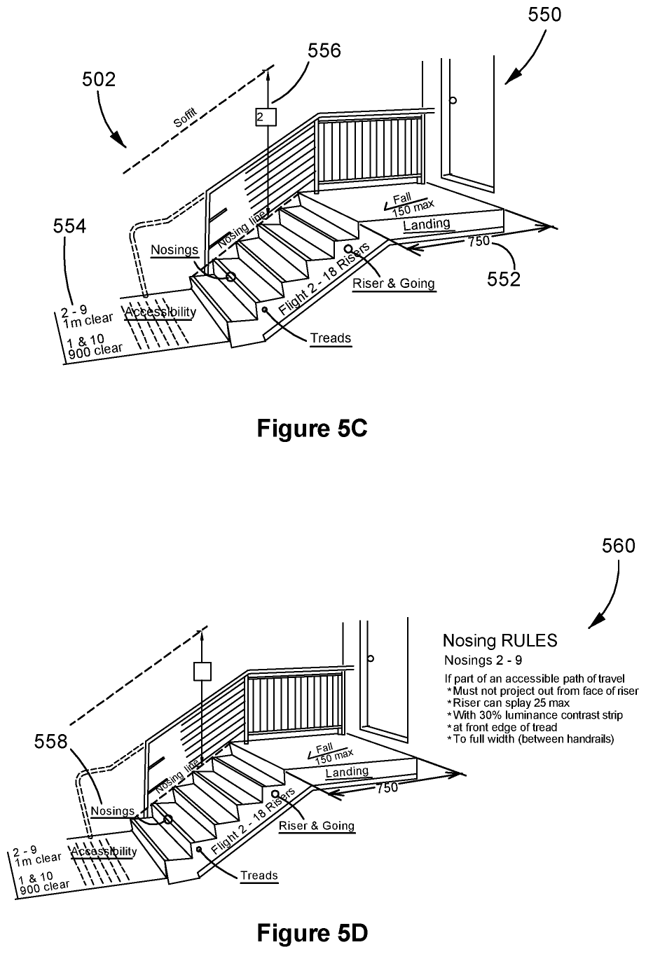

FIG. 5A shows a stair enhanced construction image 500 of a stair construction component 502. The stair component 502 includes various construction elements 504 such as barriers 506, thresholds and handrails. The enhanced construction image 500 displays a construction view 508 in the form of an image of a stairway and its related construction elements such as handrails 510, the landing 512, and accessibility elements 514. The enhanced construction image includes construction information associated with one or more of the construction elements of the construction component, in this embodiment displayed in a construction information list 520. In this example, the construction information list 520.1 lists construction information relating to clearances 522, accessibility construction information from Australian Standard 1428 (which provides minimum design requirements for new building work), and barrier construction information from National Construction Code DP3 (which provides technical design and construction requirements for fall prevention barriers).

The construction application 122 provides various methods with which a user can navigate the information provided by the visual representation of the enhanced construction image 500.

In some embodiments, selectable zones 214 are provided, for example in the form of hyperlinked labels 524. When a user selects a label 524, for example the barrier 506 label, the construction display transitions to a component detail view 530 as illustrated in FIG. 5B. The component detail view 530 includes not only a construction information list 520.2, but also a schematic representation 526 of construction information combined with the component view 508. In this exemplary embodiment, the schematic representation 526 is combined by being superimposed on the construction view 508 to provide measurement information 528 and no-climb-zone (NCZ) information 530 on the construction view 508. As can be seen in FIG. 5B, presenting the construction information in the form of a schematic representation combined with the component view (see handrail spacing 532) provides a clear and intuitive guideline to the user as compared to only providing the same information in list form (see handrail spacing 534 in list 520.2). In this embodiment, some construction information is presented in more than one format, such as the handrail spacing 532 combined with the component view, and the handrail spacing 534 displayed in the list 520.2; providing a first representation and a different second representation of the same construction information on one enhanced construction image helps the user to understand the construction information.

In some embodiments, a user may initiate a user interface gesture to navigate the information provided by the visual representation of the enhanced construction image 500. For example, the user may initiate a user interface gesture with two contact points moving apart, referred to as an “unpinch”. The user may initiate a user interface gesture with two contact points moving together, referred to as a “pinch”.

Referring to the stair enhanced construction image 500 of FIG. 5A, for example: in some embodiments, when a user applies an unpinch gesture by placing two contact points on the enhanced construction image 500 and moving the two contact points apart, the construction display transitions to a second enhanced construction image 550 of the stair component 502. The second enhanced construction image 550 includes a second set of construction information, in this example displayed as the minimum landing dimension 552, property boundary clearances 554, and nosing line bulkhead restrictions 556.

In some embodiments, the second enhanced construction image 550 may also include selectable zones 214, for example in the form of hyperlinked labels. As illustrated in FIG. 5C, if a user selects the nosings label 558, then a nosing rules list 560 is displayed.

Referring again to the stair enhanced construction image 500 of FIG. 5A: in some embodiments, if a user applies a pinch gesture by placing two contact points on the enhanced construction image 500 and moving the two contact points together, then the construction display transitions to a different enhanced construction image, in this example to a detailed enhanced construction image 600.

In this way, an interactive graphical representation of a construction region (e.g., a building) or a construction component (e.g., a stairway) is configured to be manipulated such that there is then presented on the display annotated compliance information from a relevant standard, rule and/or code, which is relevant to that construction region or construction component.

In addition to the construction view 508 of the stairway, the detailed enhanced construction image 600 also include a construction view 602 of a handrail. The detailed enhanced construction image 600 also includes detailed construction information in the form of information lists, rules lists, visual or pictorial representations, text, images, and other indicators.

A handrail information list 604 provides a list of construction information associated with the handrail construction element 606. Construction code and standards requirements are provided in text form in the list 604. The list 604 includes links 610 to the relevant standards and/or codes. In addition, construction information is provided in the form of pictorial construction information 608, combined with the handrail construction view 602. In this example, the pictorial construction information 608 includes arrows and dimensions and rotational degrees.

The detailed enhanced construction image 600 shows construction information in the form of text and links to standards/code requirements for barrier openings 612, boundaries 614, clear widths 616, landings 618, and thresholds 620. Construction information is also displayed in tabular form, for example ratings table 622 for slip resistance with respect to construction elements nosing, treads, and landings, and riser table 624 for riser and going rules. A graphical representation (or “pictorial representation”) of construction information is provided in the form of arrows with distance dimensions 626, arrows with curvature degrees 628, and two-dimensional shading 630 of zones (such as no-climb zones, NCZ).

In some embodiments, the detailed enhanced construction image 600 may include a detailed information zone 640, for example in the form of an empty display region. Upon receipt of a user input selecting or indicating an information type, the detailed enhanced construction image 600 may then display a detailed information map 642. The user input may comprise, for example, a user input (such as a finger touch) at a location corresponding to a construction element (for example at the “Tread” indicator 644), followed by a finger movement (i.e., a dragging motion) towards the detailed information zone 640. When the user removes the user input at a location corresponding to inside the information zone 640, the display then transitions so that the content displayed in the information zone 640 changes to construction information content associated with the user-selected construction element where the user input was initiated (i.e., in this example the tread and riser construction elements).

The detailed enhanced construction image 600 shows an open flight and closed flight construction view 632 that is combined with construction information relating to tread rules. The tread rules 634 are combined with the construction view 632 to display a graphical representation 636 of the riser and going dimensions for open flight and closed flight.

In some embodiments, enhanced construction images that include one or more features that may require calculations that incorporate guidelines from construction information, such as a staircase in the example depicted in FIG. 6, may provide a calculation tool accessible from the enhanced construction image displayed that includes the one or more features that require calculations. In this example, the calculation tool is accessed when a user provides a user input such as a touch input at the location of the calculation tool icon 652. Following detection of the user input, a calculation tool is displayed in the calculation zone 654.

One embodiment of a calculation tool is a stair tool 700 shown in FIG. 7. The stair tool 700 helpfully includes a graphical representation 702 of the going and riser rules, and the following user input fields 704: total rise field 706, total length field 708, and mid landings field 710. Once entered, the stair tool 700 calculates and displays the riser dimension 712 and the going dimension 714 as based on the relevant rules. Optionally, the stair tool 700 includes a name field 716 where the user can enter a project name to save the calculations.

In some embodiments, the construction application 122 may be configured to provide layered enhanced construction images that provide the user with varying levels of details of construction information. The user can navigate through the enhanced construction image layers by make a user-selection via a user input, such as a touch input.

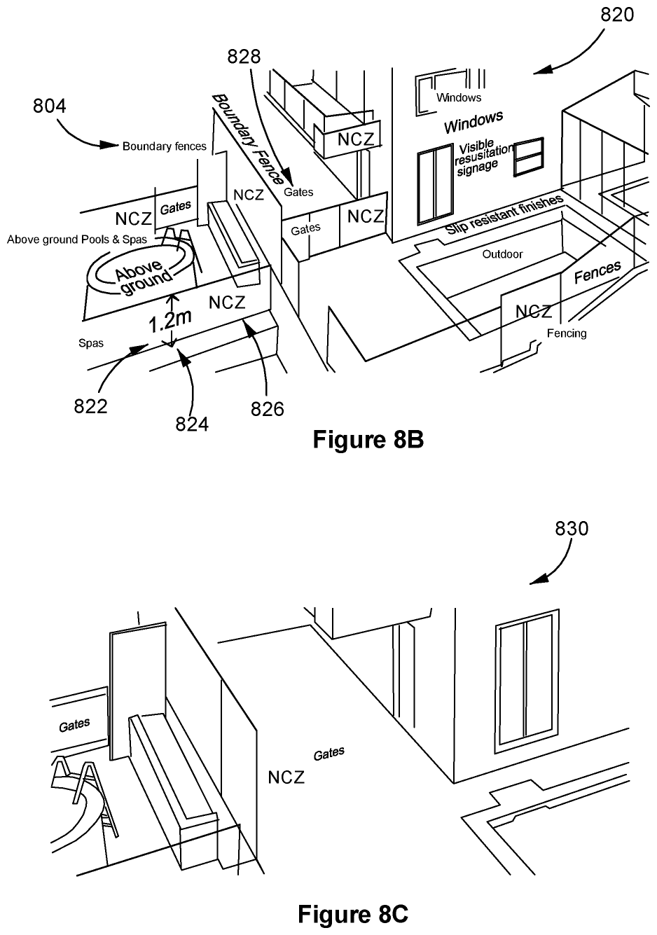

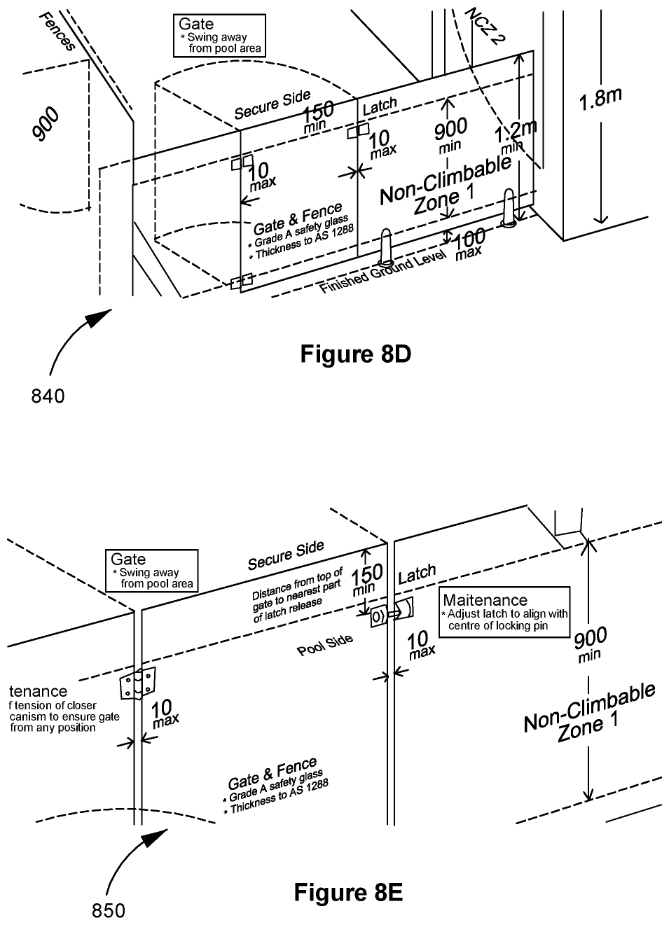

FIG. 8A shows an embodiment of a construction display 800 that includes a first level enhanced construction image 802 of construction region that includes a residential building. In the example illustrated embodiment, the first level enhanced construction image 802 does not display construction information, but instead displays construction component labels 804, for example for construction components windows 806, gates 808, and retaining walls 810. Responsive to an unpinch user touch input, the construction display 800 transitions to display a second level enhanced construction image 820 as shown in FIG. 8B.

In some embodiments, the construction view data can be organized into corresponding layers, such as a construction region layer depicting a construction region and corresponding to a first level enhanced construction image, a construction component layer depicting construction components and corresponding to a second level enhanced construction image, and so on.

In the illustrated embodiment, the second level enhanced construction image 820 shows the construction view (or a part of the construction view) of the construction region displayed in the first level enhanced construction image that includes not only the construction component labels 804, but also provides a first indication of construction information 822. The first indication of construction information 822 may include labels, measurements, animation, colour indicators or symbols to indicate that construction information is available and associated with a particular construction component. In this embodiment, the first indication of construction information 822 includes a coloured or shaded indication of no-climb-zones (NCZ) 824 as well as primary height restriction dimensions 826.

Responsive to a user input, the construction display transitions from the second level enhanced construction image 820 to display a third level enhanced construction image 830. The user input may be in the form of an unpinch. The user input may also be a touch input to one of the component labels, in this example the “gate” component label 828. The third level enhanced construction image 830 corresponds to a component level where construction information regarding the “gate” construction component is provided in a graphical representation as part of the enhanced construction image.

As described above, the user may navigate in a stepwise fashion from the first enhanced construction image, to the second enhanced construction image, and to the third enhanced construction image, but unpinching the construction display and “zooming in”.

Alternatively, the user is also able to skip directly from the first level enhanced construction image 802 straight to the third level enhanced construction image 830 by providing a user input to select the gate component label 808 as shown in FIG. 8A.

The user is able to navigate further to a fourth level enhanced construction image 840 shown in FIG. 8D, and a fifth level enhanced construction image 850 shown in FIG. 8E by providing consecutive unpinching touch inputs, thereby accessing more detailed construction information. In this way the user is able to access various different levels of detail that provide graphical representations of construction information, including construction standards, construction best practice, standards and best practice related to location (in the form of geospatial information), and risk-related information such as risk indicators associated with construction standards, rules and best practice guidelines.

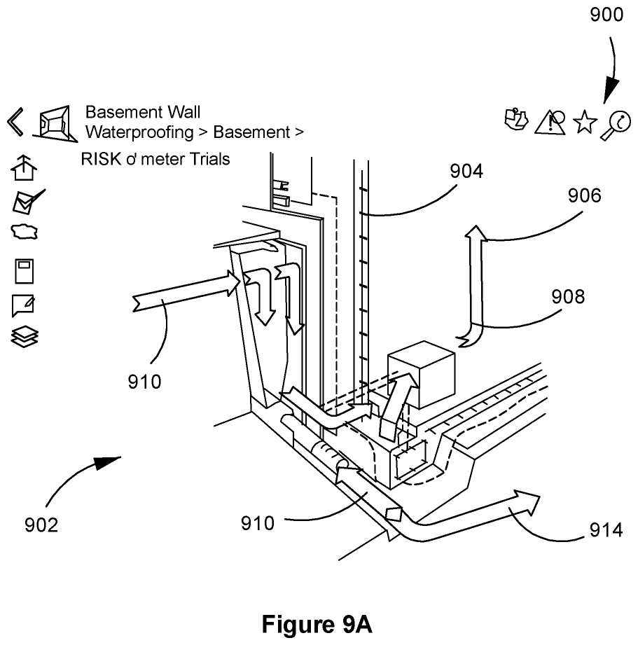

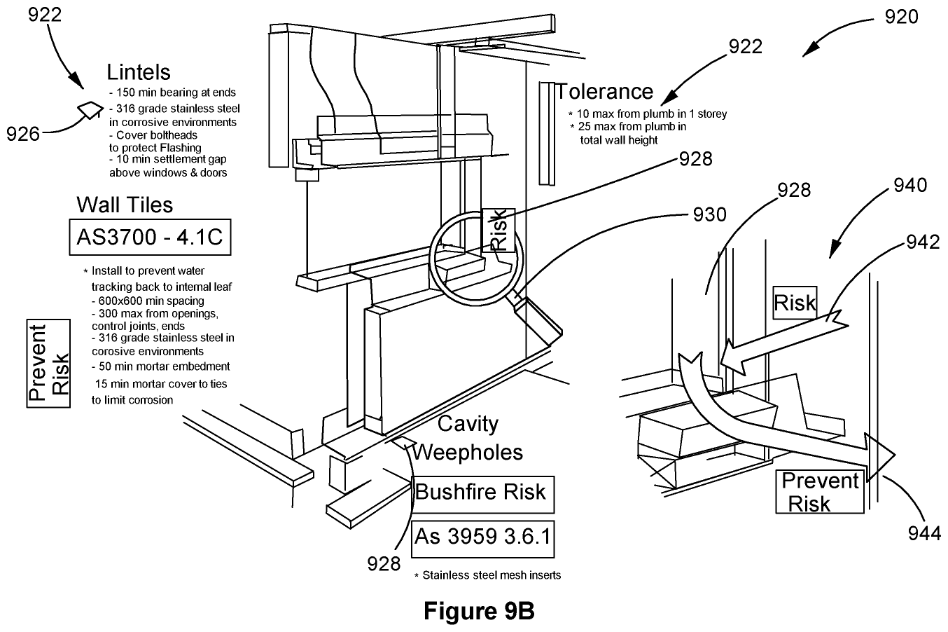

FIG. 9A shows an embodiment of a first construction display 900 that displays risk indicators 902. The risk indicators 902 include a graphical representation of risks associated with the construction component displayed, a basement wall 904 in this example. In the example of FIG. 9A, the risk indicators relate to waterproofing, and include one or more risk indications. A first risk indication 906 is provided by an arrow image that indicates the direction of water flow. A second risk indication 908 is a shading or colour to indicate either a risk (in red or a first shading), or a solution to mitigate the risk (in green or a second shading) A third risk indication 910 is a text explanation associated with the first arrow risk indication that explains the particular feature, for example the risk posed by “Groundwater Pressure” 912, or the solution provided by “Gradient down to Outlet” 914.

FIG. 9B shows an embodiment of a second construction display 920. Risk indicators 922 are included in the construction display 920 to provide a clear, instant and simple indicator to a user of a type and/or level or risk associated with a construction element, and with the construction information defining one or more construction requirements associated with the construction element. The risk indicators 922 may include one or more schematic representations such as a particular colour, an icon, an animation, etc. High risk features may be displayed with an associated warning icon 928. Risk prevention construction information (such as best practice guidelines for avoiding the potential risk associated with incorrect construction practices) maybe displayed with an associated risk information icon 926. The user interface is configured to provide more detailed construction risk information associated with the risk indicators 922 in response to a user input. For example, in the example embodiment in FIG. 9B, a user selection of a risk indicator 922, such as a finger touch on a touchscreen at the location 930 of a warning icon 928, results in the display of a detailed risk display 940. In some embodiments the risk display 940 is overlayed on the construction display 920. In other embodiments the risk display 940 replaces the construction display 920. In yet another embodiment, the display screen of the user device displays both the construction display 920 as well as the risk display 940 next to one another. The risk display 940 includes detailed construction risk information, for example: (1) a risk consequence indicator 942 (which may be in the form of text, a colour to indicate risk level e.g., shades of red, and/or other schematic representation such as an arrow representing movement, and/or an animation), and (2) a risk avoidance indicator 944, being construction requirements (from building codes, building standards, best practice guidelines etc.) for the purpose of avoiding or reducing the consequences of the construction risk.

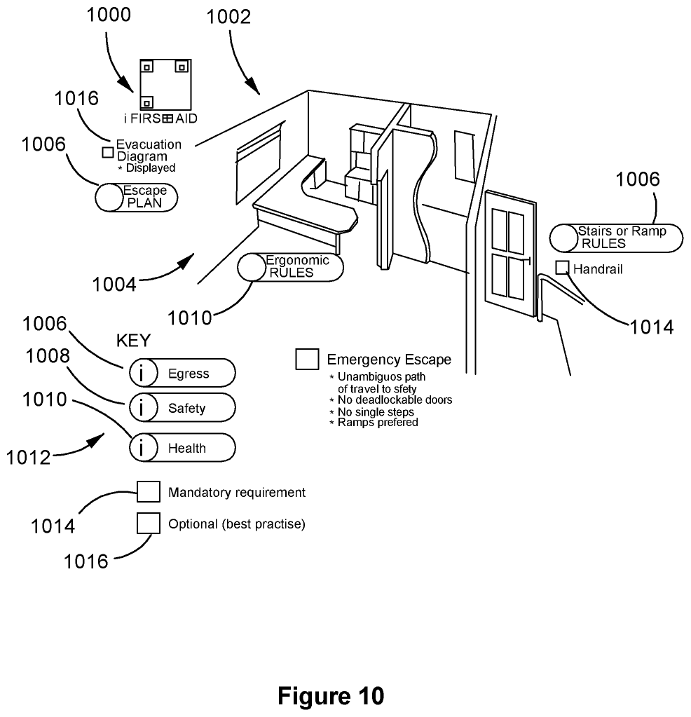

FIG. 10 illustrates an embodiment of the application 122 that may be used for workplace compliance and the implementation of workplace health and arrangement standards, rules, and/or acceptable practice Enhanced construction image 1000 includes a construction view 1002 of a workplace 1004 (for example an office or a home office) Enhanced construction image 1000 includes construction information relating to egress requirements 1006, safety requirements 1008 and health requirements 1010; these requirements are indicated (for example using colour coding), and a key 1012 is provided to distinguish the various requirements. Furthermore, whether the construction information provided in the enhanced construction image 1000 relates to mandatory requirements 1014 or optional best practice guidelines 1016 is also indicated, for example via colour coding or other indicators.

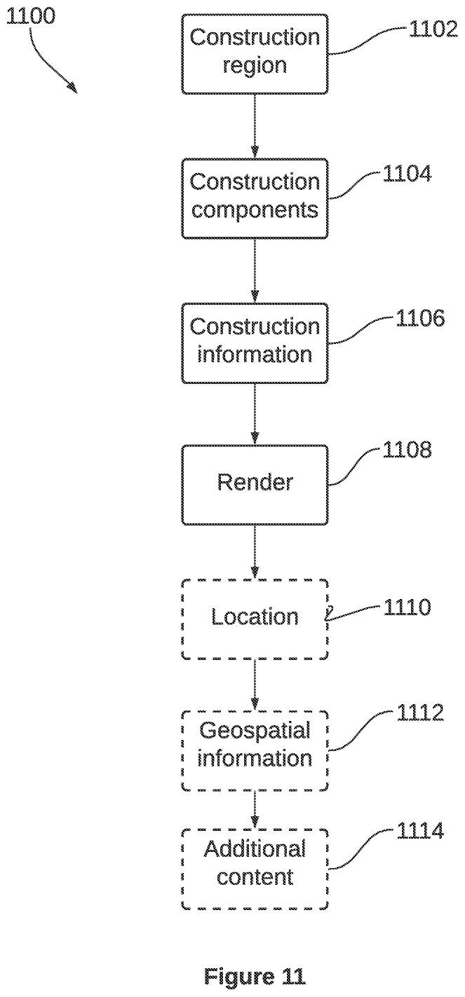

Referring to FIG. 11 of the drawings, a method 1100 for presenting construction-related information to a user includes, at 1102 receiving a user selection for a construction region and at 1104 retrieving image data for the construction components that form part of the selected construction region. At 1106 construction information associated with one or more of the construction components is retrieved, and at 1108 an enhanced construction image is rendered that combines the retrieved image data for the construction components with a schematic representation of the construction information. In some embodiments, the schematic representation of the construction information may include text, an image or visual mark such as an arrow or dimension indicator, and/or an indicator such as a colour or sign that provides an indication associated with the construction information (for example an indicator of a level of risk).

Optionally, in some embodiments, the method 1100 includes at 1112 ascertaining a location of the computing device with which the method 1100 is performed, for example by receiving sensor data indicative of the location. At step 1112 geospatial information associated with the location is retrieved, and at 1114 an enhanced construction image with additional content is rendered, thereby presenting construction-related information associated with a current location of the computing device. The additional content comprises construction requirements associated with the geospatial information, for example building dimensions and/or material required to withstand or accommodate location-specific parameters (e.g., relating to wind loading for the selected area, temperature ranges, rainfall ranges, potential pests, etc.)

Each of the above identified modules and applications corresponds to a set of executable instructions for performing one or more functions described above and the methods described in this application (e.g., the computer-implemented methods and other information processing methods described herein). These modules (i.e., sets of instructions) need not be implemented as separate software programs, procedures, or modules, and thus various subsets of these modules are, optionally, combined or otherwise re-arranged in various implementations. In some implementations, the memory 120 stores a subset of the modules and data structures identified above. In some implementations, the memory 120 stores additional modules and data structures not described above.

It will be understood to persons skilled in the art of the invention that many modifications may be made without departing from the spirit and scope of the invention.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

1-25. (canceled)

26. A method of generating a virtual reality (VR) or augmented reality (AR) interface on a computing device using a sensor of the computing device and machine learning (ML), comprising:
receiving, by a virtual reality device or an augmented reality device, a user selection for a construction region from a graphical user interface displayed by the virtual reality device or the augmented reality device;
retrieving, by the virtual reality device or the augmented reality device, image data for one or more construction components that form part of the construction region as selected;
retrieving, by the virtual reality device or the augmented reality device, construction information defining a construction requirement associated with one or more of the construction components;
rendering, by the virtual reality device or the augmented reality device, a first enhanced construction image in a virtual reality or augmented reality environment shown in a display device that combines the retrieved image data for the construction components with a schematic representation of the construction information;
receiving, by the virtual reality device or the augmented reality device, sensor data indicative of a location of the virtual reality device or the augmented reality device;
ascertaining, by the virtual reality device or the augmented reality device, a current location or geographical area of the computing device based on the sensor data as received;
retrieving, by the virtual reality device or the augmented reality device, geospatial information associated with both the current location or geographical area and one or more of the construction components;
rendering, by the virtual reality device or the augmented reality device, a second enhanced construction image that comprises additional content incorporating the retrieved geospatial information;
providing, by the virtual reality device or the augmented reality device to a machine learning classification routine, feature classifiers containing characteristics for identifying pixels which represent the construction components; and
based on the feature classifiers, identifying, by the virtual reality device or the augmented reality device, construction features and removing superfluous portions of an image unrelated to the identified construction features,
wherein the machine learning classification routine is one of a support vector machine, a neural network, a naive Bayes, and a random forest routine, and
wherein removing the superfluous portions of the image is performed using at least one of a spatial heuristic algorithm and a machine learning technique that compare pixels in a panoramic view to sample pixels.

27. The method of claim 26, wherein the schematic representation of the construction information comprises at least one of: an image, a visual mark, a dimension indicator, a risk indicator, an animation, and a color indicator.

28. The method of claim 26, further comprising:
detecting, by the virtual reality device or the augmented reality device, a change in location of the virtual reality device or the augmented reality device from the current location to a new location associated with new geospatial information, wherein detecting the change in location comprises ascertaining a change from the geospatial information to the new geospatial information.

29. A method of generating a user interface for presenting construction-related information on an electronic device, comprising:
receiving, by a computing device, a user selection for a construction region;
retrieving, by the computing device, image data for one or more construction components that form part of the selected construction region;
retrieving, by the computing device, construction information defining a construction requirement associated with one or more of the construction components; and
rendering, by the computing device, a first enhanced construction image on a display device that combines the retrieved image data for the construction components with a schematic representation of the construction information.

30. The method of claim 29, wherein the schematic representation of the construction information comprises at least one of: an image, a visual mark, a dimension indicator, a risk indicator, an animation, and a color indicator.

31. The method of claim 29, further comprising:
receiving, by the computing device, sensor data indicative of a location of the computing device;
ascertaining, by the computing device, a current location or geographical area of the computing device based on the received sensor data;
retrieving, by the computing device, geospatial information associated with both the current location or geographical area and one or more of the construction components;
rendering, by the computing device, a second enhanced construction image that comprises additional content incorporating the retrieved geospatial information.

32. The method of claim 31, further comprising:
detecting, by the computing device, a change in location of the computing device from the current location to a new location associated with new geospatial information, wherein detecting the change in location comprises ascertaining a change from the geospatial information to the new geospatial information.

33. The method of claim 32, further comprising selecting the new location for a new enhanced construction image and displaying, as part of the new enhanced construction image, the new geospatial information.

34. A method of generating a graphical user interface for presenting construction standards, comprising:
rendering, by a computing device, a first constriction image representing one or more of a section, or exploded, or cutaway, view of a building on a display screen of a computer processing system;
providing, by the computing device, zoomable, clickable, or otherwise selectable areas, on the display screen of the computer processing system, which represent relevant building elements; and
presenting, on the display screen of the computer processing system, in response to a user clicking or otherwise selecting the relevant areas on the screen, detailed information relating to construction standards for the relevant element or elements,
wherein the detailed information presentation comprising presenting annotated images of the element, annotated with a visual representation of the construction standards that comprises at least one of: an image, a visual mark, a dimension indicator, and a color indicator.

35. The method of claim 34, further comprising:
receiving, by the computing device, global positioning system (GPS) sensor data indicative of a location of the computer processing system;
ascertaining, by the computing device, a current location or geographical area of the computer processing system based on the received sensor data;
retrieving, by the computing device, geospatial information associated with both the current location or geographical area and one or more of the building elements; and
rendering, by the computing device, a second construction image that comprises additional content incorporating the retrieved geospatial information, wherein the geospatial information comprises at least one of: wind loading, temperature ranges, rainfall ranges, and insect pests;
wherein the additional content comprises construction requirements associated with the geospatial information.

36. A system for generating a graphical user interface (GUI) for facilitating compliance with building or workplace health standards, comprising:
a computer processing system comprising a hardware processor and memory having program instructions stored thereon that, when executed, direct the computing processing system to generate a graphical user interface configured to:
represent one or more of a section, or exploded, or cutaway, view of a building on a display screen as an image; and
receive a user input indicative of a selected building element on the building representation;
wherein the computer processing system is further directed to cause detailed information relating to construction standards of the relevant element or elements to be displayed on a screen of the computer processing system, in response to the received user input; and
wherein the computer processing system is further directed to display the detailed construction standard information as a graphical representation comprising annotated images of the element.

37. The system of claim 36, wherein the annotations on the image comprise dimensions from one element to another element, in accordance with a relevant standard, wherein the dimensions are presented as a graphical representation superimposed on the image of the building.
